(19) United States
(12) Patent Application Publication
(10) Pub. No.: US 2008/0315240 A1
(43) Pub. Date: Dec. 25, 2008

(54) III-Nitride Semiconductor light Emitting Device

(75) Inventors: Chang Tae Kim, Kyunggi-do (KR); Hyun-Min Jung, Kyunggi-do (KR); Tae Hee Lee, Chungnam-do (KR); Byeong Kyun Choi, Kyunggi-do (KR); Hyun Suk Kim, Kyunggi-do (KR); Gi Yeon Nam, Kyunggi-do (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gyungbuk (KR)

(21) Appl. No.: 12/196,066

(22) Filed: Aug. 21, 2008

Related U.S. Application Data
(63) Continuation of application No. PCT/KR2007/004219, filed on Aug. 31, 2007.

(30) Foreign Application Priority Data
Aug. 31, 2006 (KR) 10-2006-0083393
Sep. 30, 2006 (KR) 10-2006-0096716
Dec. 30, 2006 (KR) 10-2008-0139164

(51) Int. Cl. H01L 33/00

(52) U.S. Cl. 257/99; 257/E33.062

(57) ABSTRACT

The present disclosure relates to an III-nitride semiconductor light emitting device, particularly, an electrode structure thereof. The III-nitride semiconductor light emitting device includes a substrate, a plurality of III-nitride semiconductor layers grown on the substrate, and composed of a first III-nitride semiconductor layer with first conductivity, a second III-nitride semiconductor layer with second conductivity different from the first conductivity, and an active layer positioned between the first III-nitride semiconductor layer and the second III-nitride semiconductor layer, for generating light by recombination of electrons and holes, and a hole passing through the substrate and the plurality of III-nitride semiconductor layers.

### CROSS-REFERENCE TO RELATED APPLICATIONS

This application is a continuation of PCT International Application No. PCT/KR2007/004219 filed on Aug. 31, 2007. This application claims the benefit of Korean Application No. 10-2006-0083393, filed Aug. 31, 2006, Korean Application No. 10-2006-0096716 filed Sep. 30, 2006, and Korean Application No. 10-2006-0139164 filed Dec. 30, 2006. The entire disclosures of the above applications are incorporated herein by reference.

### FIELD

The present disclosure generally relates to a III-nitride semiconductor light emitting device, particularly, to a vertical III-nitride semiconductor light emitting device with a hole passing through the device, and more particularly, to an electrode structure of a vertical III-nitride semiconductor light emitting device. The III-nitride semiconductor light emitting device means a light emitting device such as a light emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view illustrating one example of a conventional III-nitride semiconductor light emitting device. The III-nitride semiconductor light emitting device includes a substrate 100, a buffer layer 200 epitaxially grown on the substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a p-side electrode 600 formed on the p-type nitride semiconductor layer 500, a p-side bonding pad 700 formed on the p-side electrode 600, an n-side electrode 800 formed on the n-type nitride semiconductor layer 300 exposed by mesa-etching the p-type nitride semiconductor layer 500 and the active layer 400, and a protection film 900.

In the case of the substrate 100, a GaN substrate can be used as a homo-substrate, and a sapphire substrate, an SiC substrate or an Si substrate can be used as a hetero-substrate. However, any type of substrate that can grow a nitride semiconductor layer thereon can be employed. In the case that the SiC substrate is used, the n-side electrode 800 can be formed on the side of the SiC substrate.

The nitride semiconductor layers epitaxially grown on the substrate 100 are mostly grown by metal organic chemical vapor deposition (MOCVD).

The buffer layer 200 serves to overcome differences in lattice constant thermal expansion coefficient between the hetero-substrate 100 and the nitride semiconductor layers. U.S. Pat. No. 5,122,845 mentions a technique of growing an AlN buffer layer with a thickness of 100 to 500 Å on a sapphire substrate at 380 to 800° C. In addition, U.S. Pat. No. 5,290,393 suggests a technique of growing an Al_{(X)}Ga₍₁₋ₓ₎N (0≦x≦1) buffer layer with a thickness of 10 to 5000 Å on a sapphire substrate at 200 to 900° C. Moreover, PCT Publication No. WO/05/053042 suggests a technique of growing an SiC buffer layer (seed layer) at 600 to 990° C., and growing an In_{(X)}Ga₍₁₋ₓ₎N (0≦x≦1) thereon.

In the n-type nitride semiconductor layer 300, at least the n-side electrode 800 formed region (n-type contact layer) is doped with a dopant. Preferably, the n-type contact layer is made of GaN and doped with Si. U.S. Pat. No. 5,733,796 mentions a technique of doping an n-type contact layer at a target doping concentration by adjusting a mixture ratio of Si and another source material.

The active layer 400 generates light quanta (light) by recombination of electrons and holes. Normally, the active layer 400 contains In_{(X)}Ga₍₁₋ₓ₎N (0≦x≦1) and has single or multi-quantum well layers. PCT Publication No. WO/02/021121 suggests a technique of doping some portions of a plurality of quantum well layers and barrier layers.

The p-type nitride semiconductor layer 500 is doped with an appropriate dopant such as Mg, and provided with p-type conductivity by an activation process. U.S. Pat. No. 5,247,533 teaches a technique of activating a p-type nitride semiconductor layer by electron beam irradiation. Moreover, U.S. Pat. No. 5,306,662 shows a technique of activating a p-type nitride semiconductor layer by annealing over 400° C. PCT Publication No. WO 05/022655 suggests a technique of endowing a p-type nitride semiconductor layer with p-type conductivity without an activation process, by using ammonia and a hydrazine-based source material together as a nitrogen precursor for growing the p-type nitride semiconductor layer.

The light transmitting electrode 600 is provided to facilitate current supply to the whole p-type nitride semiconductor layer 500. U.S. Pat. No. 5,563,422 mentions a technique associated with a light transmitting electrode composed of Ni and Au and formed almost on the entire surface of a p-type nitride semiconductor layer in ohmic-contact with the p-type nitride semiconductor layer. In addition, U.S. Pat. No. 6,515,306 suggests a technique of forming an n-type superlattice layer on a p-type nitride semiconductor layer, and forming a light transmitting electrode made of ITO thereon.

Meanwhile, the light transmitting electrode 600 can be formed thick not to transmit but to reflect light toward the substrate 100. This technique is called a flip chip technique. U.S. Pat. No. 6,194,743 teaches a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire bonding. U.S. Pat. No. 5,563,422 suggests a technique of forming an n-side electrode with Ti and Al, and U.S. Pat. No. 5,652,434 suggests a technique of making a p-side bonding pad directly contact the p-type nitride semiconductor layer by removing some portion of a light transmitting electrode.

The protection film 900 can be made of SiO₂, and may be omitted.

In the meantime, the n-type nitride semiconductor layer 300 or the p-type nitride semiconductor layer 500 can be constructed as single or plural layers. PCT Publication No. WO 00/010595 mentions a technique of adding a superlattice structure, and changing, in the superlattice, doping concentration of nitride semiconductor layers in various ways, or changing a composition of

Al_{(X)}Ga_{(y)}In_{(1-x-y)}N.

In general, in the case of the III-nitride semiconductor light emitting device, the substrate 100 is mostly made of a sapphire. As the sapphire substrate is a current insulator, an electrode for supplying current is positioned at one side of the device in a horizontal direction. Some of the light generated in the active layer 400 is externally emitted to influence the external quantum efficiency, but other of the light is confined in the sapphire substrate 100 and the nitride semiconductor layers and vanished as heat. Moreover, as the current is applied in the horizontal direction, a current density is unbalanced in the light emitting device, which has a detrimental effect on the performance of the device.

Therefore, many researches have been made on techniques of manufacturing a high efficiency light emitting device with a vertical electrode structure by growing a plurality of nitride semiconductor layers on the sapphire substrate 100, and eliminating the sapphire substrate 100. Normally, a method using a laser is employed as a method of eliminating the sapphire substrate 100. When laser beams are irradiated to the lower portion of the sapphire substrate 100, the sapphire substrate 100 does not absorb but transmits the laser beams. On the contrary, the nitride semiconductor layer absorbs the laser beams, so that III-group element and nitrogen element separate from each other. As Ga which is mainly used as III-group element keeps a liquid phase at a normal temperature, the sapphire substrate 100 and the nitride semiconductor layers separate from each other. However, according to the method using laser, while the laser beams are irradiated, a high temperature heat is generated to adversely affect the device. Moreover, the nitride semiconductor layers may be broken due to the stress between the sapphire substrate 100 and the nitride semiconductor layers.

FIG. 2 is a view illustrating one example of a vertical III-nitride semiconductor light emitting device (Korean Patent Application No. 2006-35149) of which the present applicant holds a right. The III-nitride semiconductor light emitting device includes a sapphire substrate 100 with a groove 110 formed therein, a buffer layer 200, an n-type nitride semiconductor layer 300, an active layer 400 for generating light by recombination of electrons and holes, a p-type nitride semiconductor layer 500, a p-side electrode 600, and a p-side bonding pad 700. An opening 910 is formed along the groove 110 in the plurality of nitride semiconductor layers 200, 300, 400 and 500. A first n-side electrode 800a electrically contacts the n-type nitride semiconductor layer 300 through the opening 910, and a second n-side electrode 800b electrically contacts the n-type nitride semiconductor layer 300 through the groove 110, to constitute the vertical light emitting device. Here, the first n-side electrode 800a can be omitted.

The opening 910 corresponding to the groove 110 can be formed by growing the plurality of nitride semiconductor layers 200, 300, 400 and 500 in a condition of inhibiting the lateral growth. For example, as for the n-type nitride semiconductor layer 300, TMGa, NH₃ and SiH₄ are supplied by 365 seem, 11 slm and 8.5 sim, respectively, and treated at a growth temperature of 1050° C., a doping concentration of 3×10¹⁸/cm³ and a pressure of 300 to 500 torr, so that 4 μm of GaN layer is grown with the opening 910 (in this case, a circular groove 110 with a diameter of 30 μm is used).

Meanwhile, as the opening 910 is formed at the upper portion of the light emitting device, in order to smoothly supply current, it is necessary to appropriately arrange the p-side bonding pad 700 and/or a branch electrode extending therefrom in consideration of the opening 910.

In addition, as the groove 110 and the opening 910 pass through the light emitting device, a material such as epoxy supposed to be positioned at the lower portion of the light emitting device may rise to the upper portion of the light emitting device in packaging.

Moreover, in the case that both the first n-side electrode 800a and the second n-side electrode 800b are formed in the light emitting device, the instability of the electrical contact thereof may cause the current leakage and the unbalance in current density.

### SUMMARY

This section provides a general summary of the disclosure, and is not a comprehensive disclosure of its full scope or all of its features.

According to one aspect of the present disclosure, a III-nitride semiconductor light emitting device comprises a substrate including a first face and a second face opposite to the first face, a groove being formed from the first face to the second face; a plurality of III-nitride semiconductor layers including a buffer layer grown on the first face of the substrate with the groove formed therein, an n-type III-nitride semiconductor layer epitaxially grown over the buffer layer, an active layer epitaxially grown over the n-type III-nitride semiconductor layer, for generating light by recombination of electrons and holes, and a p-type III-nitride semiconductor layer epitaxially grown over the active layer; a p-side electrode and a p-side bonding pad formed over the p-type III-nitride semiconductor layer; the plurality of III-nitride semiconductor layers being provided with an opening generated by the groove formed in the first face of the substrate; a first n-side electrode formed at the n-type III-nitride semiconductor layer through the opening, and a second n-side electrode formed at the n-type III-nitride semiconductor layer through the groove exposed by polishing the second face of the substrate, the first n-side electrode and the second n-side electrode electrically contacting each other; and an auxiliary metal electrode formed at the outer walls of the first n-side electrode and the second n-side electrode.

According to another aspect of the present disclosure, a III-nitride semiconductor light emitting device includes a substrate; and a plurality of III-nitride semiconductor layers grown over the substrate, and composed of a first III-nitride semiconductor layer with first conductivity, a second III-nitride semiconductor layer with second conductivity different from the first conductivity, and an active layer positioned between the first III-nitride semiconductor layer and the second III-nitride semiconductor layer, for generating light by recombination of electrons and holes, the III-nitride semiconductor light emitting device, comprising a hole connected from the substrate to the first III-nitride semiconductor layer; and a plating layer positioned in the hole and electrically connected to the first III-nitride semiconductor layer.

According to another aspect of the present disclosure, a III-nitride semiconductor light emitting device includes a substrate; and a plurality of III-nitride semiconductor layers grown over the substrate, and composed of a first III-nitride semiconductor layer with first conductivity, a second III-nitride semiconductor layer with second conductivity different from the first conductivity, and an active layer positioned between the first III-nitride semiconductor layer and the second III-nitride semiconductor layer, for generating light by recombination of electrons and holes, the III-nitride semiconductor light emitting device, comprising a hole starting from the substrate and passing through the plurality of III-nitride semiconductor layers; a first electrode electrically connected from the side of the plurality of III-nitride semiconductor layers to the first III-nitride semiconductor layer through the hole; a second electrode electrically connected from the substrate side to the first III-nitride semiconductor layer through the hole; and an auxiliary electrode for connecting the first electrode and the second electrode.

According to another aspect of the present disclosure, a III-nitride semiconductor light emitting device comprises a substrate; a plurality of III-nitride semiconductor layers grown over the substrate, and composed of a first III-nitride semiconductor layer with first conductivity, a second III-nitride semiconductor layer with second conductivity different from the first conductivity, and an active layer positioned between the first III-nitride semiconductor layer and the second III-nitride semiconductor layer, for generating light by recombination of electrons and holes; at least one hole passing through the substrate and the plurality of III-nitride semiconductor layers; a pad electrode electrically contacting the second III-nitride semiconductor layer; and a branch electrode extending from the pad electrode.

According to another aspect of the present disclosure, a III-nitride semiconductor light emitting device includes a substrate; and a plurality of III-nitride semiconductor layers grown over the substrate, and composed of a first III-nitride semiconductor layer with first conductivity, a second III-nitride semiconductor layer with second conductivity different from the first conductivity, and an active layer positioned between the first III-nitride semiconductor layer and the second III-nitride semiconductor layer, for generating light by recombination of electrons and holes, the III-nitride semiconductor light emitting device, comprising: a hole passing through the substrate and the plurality of III-nitride semiconductor layers, and being positioned in a non-central portion of the III-nitride semiconductor light emitting device; and a pad electrode electrically contacting the second III-nitride semiconductor layer.

According to another aspect of the present disclosure, a III-nitride semiconductor light emitting device comprises a substrate in which a groove is formed; a plurality of III-nitride semiconductor layers being formed over the substrate, and including an active layer for generating light by recombination; an opening formed on the groove along the plurality of III-nitride semiconductor layers; and a protection film for blocking communication to the opening.

According to another aspect of the present disclosure, a III-nitride semiconductor light emitting device comprises a substrate in which a groove is formed; a plurality of III-nitride semiconductor layers being formed on the substrate, and including an active layer for generating light by recombination, and a first III-nitride semiconductor layer positioned between the substrate and the active layer; an opening formed on the groove along the plurality of III-nitride semiconductor layers; a first electrode electrically contacting the first III-nitride semiconductor layer through the groove; and a second electrode electrically contacting the first III-nitride semiconductor layer through the first electrode.

Further areas of applicability will become apparent from the description provided herein. The description and specific examples in this summary are intended for purposes of illustration only and are not intended to limit the scope of the present disclosure.

### DESCRIPTION OF DRAWINGS

FIG. 1 is a view illustrating one example of a conventional III-nitride semiconductor light emitting device;

FIG. 2 is a view illustrating one example of a vertical III-nitride semiconductor light emitting device (Korean Patent Application No. 2006-35149) of which the present applicant holds a right;

FIG. 3 is a view illustrating one example of a III-nitride semiconductor light emitting device according to an embodiment of the present disclosure;

FIG. 4 is a view schematically illustrating a process of electro plating;

FIGS. 5 to 8 are photographs showing an auxiliary metal electrode of the III-nitride semiconductor light emitting device according to an embodiment of the present disclosure;

FIG. 9 is a top view illustrating one example of the III-nitride semiconductor light emitting device according to an embodiment of the present disclosure;

FIG. 10 is a view illustrating one example of a p-side electrode structure of the III-nitride semiconductor light emitting device according to an embodiment of the present disclosure;

FIG. 11 is a view illustrating another example of the p-side electrode structure of the III-nitride semiconductor light emitting device according to an embodiment of the present disclosure;

FIG. 12 is a view illustrating yet another example of the p-side electrode structure of the III-nitride semiconductor light emitting device according to an embodiment of the present disclosure;

FIG. 13 is a view illustrating yet another example of the p-side electrode structure of the III-nitride semiconductor light emitting device according to an embodiment of the present disclosure;

FIG. 14 is a view illustrating yet another example of the p-side electrode structure of the III-nitride semiconductor light emitting device according to an embodiment of the present disclosure;

FIGS. 15 and 16 are views illustrating yet another examples of the p-side electrode structure of the III-nitride semiconductor light emitting device according to an embodiment of the present disclosure;

FIGS. 17 to 19 are views illustrating yet another examples of the p-side electrode structure of the III-nitride semiconductor light emitting device according to an embodiment of the present disclosure;

FIG. 20 is a view illustrating another example of the III-nitride semiconductor light emitting device according to an embodiment of the present disclosure;

FIGS. 21 to 23 are SEM photographs showing a protection film according to an embodiment of the present disclosure;

FIG. 24 is a view illustrating yet another example of the III-nitride semiconductor light emitting device according to an embodiment of the present disclosure; and

FIGS. 25 and 26 are SEM photographs taken when a groove is excessively filled for explanation's sake.

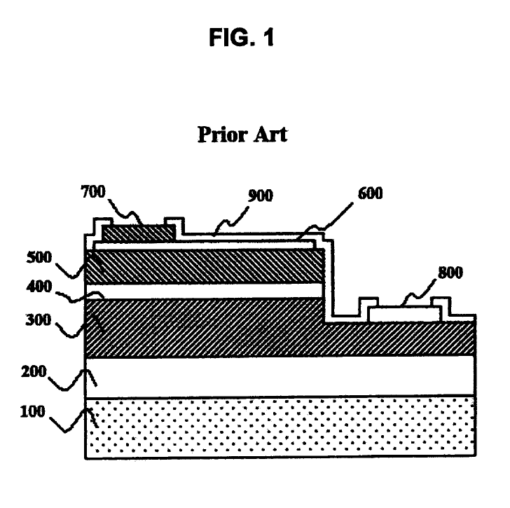

### DETAILED DESCRIPTION

The present disclosure is to provide a vertical III-nitride semiconductor light emitting device.

In an embodiment of the present disclosure is to provide an electrode structure for a vertical III-nitride semiconductor light emitting device.

In another embodiment of the present disclosure is to provide a vertical III-nitride semiconductor light emitting device with an electrode structure using plating.

According to the present disclosure, not only problems of the light emitting device with two electrodes positioned at one side but also problems of the vertical light emitting device formed by removing the substrate, can be solved.

The present disclosure will now be described in detail with reference to the accompanying drawings.

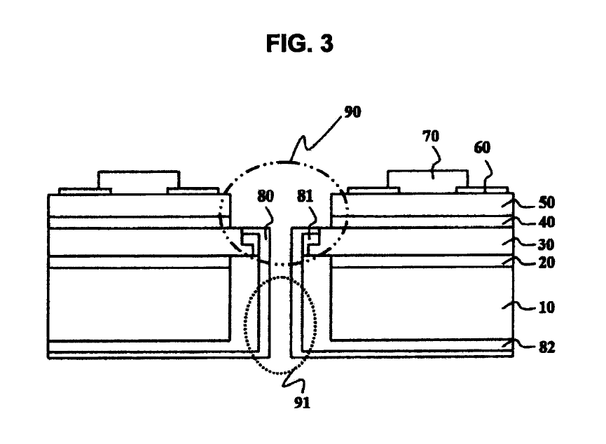

FIG. 3 is a view illustrating one example of an III-nitride semiconductor light emitting device according to the present disclosure. The III-nitride semiconductor light emitting device includes a substrate 10 with a groove 91 formed therein, a buffer layer 20 epitaxially grown on the substrate 10, an n-type nitride semiconductor layer 30 epitaxially grown on the buffer layer 20, an active layer 40 grown on the n-type nitride semiconductor layer 30, for generating light by recombination of electrons and holes, a p-type nitride semiconductor layer 50 epitaxially grown on the active layer 40, a p-side electrode 60 which is a light transmitting electrode formed on the p-type nitride semiconductor layer 50, a p-side bonding pad 70 grown on the p-side electrode 60, a first n-side electrode 81 formed on the n-type nitride semiconductor layer 30 exposed by an opening 90, a second n-side electrode 82 electrically contacting the n-type nitride semiconductor layer 30 through the groove 91, and an auxiliary metal electrode 80 formed at the outer walls of the first n-side electrode 81 and the second n-side electrode 82.

A laser having a wavelength of 355 nm is used to form the groove 91 in the substrate 10. In a state where the laser is focused, a circular, elliptical or polygonal groove 91 with a diameter of a few to a few hundreds μm can be formed. In addition, a depth of the groove 91 can be adjusted from a few to a few hundreds μm by energy of the laser. The groove 91 may be formed to pass through the substrate 10.

The laser used to form the groove 91 is a diode pumped solid state (DPSS) laser using a neodymium-doped yttrium oxide as an active medium, and having a wavelength of 532 nm. An output of the laser is 10 W (10 to 100 KHz) and a drilling speed thereof ranges from 20 to 50 holes/sec.

The plurality of III-nitride semiconductor layers including the n-type nitride semiconductor layer 30 epitaxially grown on the buffer layer 20, the active layer 40 for generating light by recombination of electrons and holes, and the p-type nitride semiconductor layer 50 are grown without the lateral growth by controlling growth conditions such as a growth temperature, a growth speed and a growth pressure. The opening 90 starting from the groove 91 of the substrate 10 is formed in the plurality of nitride semiconductor layers grown in the growth conditions of inhibiting the lateral growth. Alternatively, after the plurality of III-nitride semiconductor layers are grown to cover the groove 91, the opening 90 can be formed therein by etching.

A process of exposing the n-type nitride semiconductor layer 30 is performed after the p-side electrode 60 is formed on the p-type nitride semiconductor layer 50. Dry etching and/or wet etching is used to expose the n-type nitride semiconductor layer 30. In order to enlarge an exposed surface area, the n-type nitride semiconductor layer 30 is preferably etched to have one step.

The p-side bonding pad 70 is formed on the p-type nitride semiconductor layer 50 and the p-side bonding pad 60 after the formation of the p-side electrode 60. During this process, the first n-side electrode 81 is formed on the n-type nitride semiconductor layer 30 exposed to the opening 90. The first n-side electrode 81 serves to enlarge an electrode contact area for current supply to the n-type nitride semiconductor layer 30.

A process of polishing the rear face of the substrate 10 is carried out after the formation of the p-side bonding pad 70 and the first n-side electrode 81. The polishing process is performed at least to the groove-formed region of the substrate 10 to expose the groove 91 starting from the front face of the substrate 10. The second n-side electrode 82 is formed after the process of polishing the rear face of the substrate 10. The second n-side electrode 82 is formed below the n-type nitride semiconductor layer 30 through the groove 91, and electrically contacts the first n-side electrode 81. Preferably, the second n-side electrode 82 is formed on the whole rear face of the substrate 10 to function as a reflection film.

As for an electro-plating, an object to be plated connects to a (−) terminal and a plating material connects to a (+) terminal. Here, the plating material is a solution containing metal ions of high electrical conductivity, such as Au, Ag, Cu and Al. When current is applied to the solution containing metal ions of high electrical conductivity, the reduction occurs in the (−) terminal and the oxidation occurs in the (+) terminal. The metal ions contained in the solution constitute the auxiliary metal electrode 80 due to the reduction of the object to be plated which has connected to the (−) terminal.

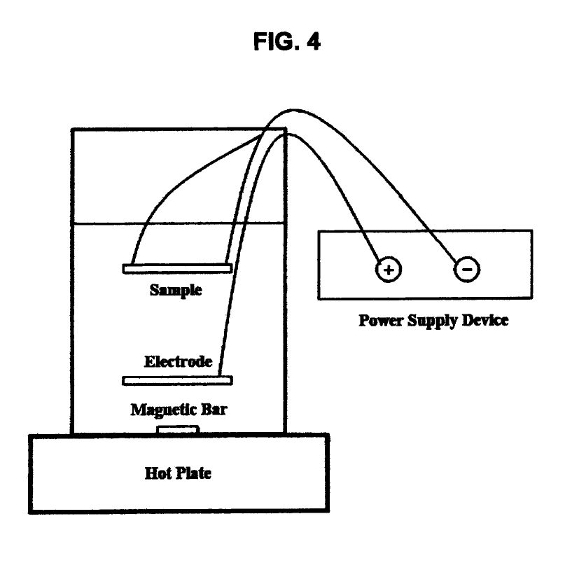

According to the present disclosure, the auxiliary metal electrode 80 is formed by using a solution containing Cu ions. In the conditions of the electroplating process, in order to facilitate the plating in the groove 91, a wafer and a plating material are positioned to be level with each other. In addition, so as to uniformize the plating, a turbulent flow is generated in a container by a magnetic bar, which is shown in FIG. 4.

In the formation of the auxiliary metal electrode 80, a possible lowest current is applied in the plating process to improve a film quality of the auxiliary metal electrode 80. According to the present disclosure, a current of 150 mA is applied, and the auxiliary metal electrode 80 is formed by about 1700 Å per minute.

As the auxiliary metal electrode 80 is formed, a thermal problem and an electrical contact problem caused by a current rush resulting from a small thickness of the first n-side electrode 81 can be solved by a comparatively easy electro-plating, and reliability of the device can be improved. Moreover, as the auxiliary metal electrode 80 is formed by the electro-plating after the formation of the second n-side electrode 82, the first n-side electrode 81 and the second n-side electrode 82 stably contact each other to improve an electrical characteristic.

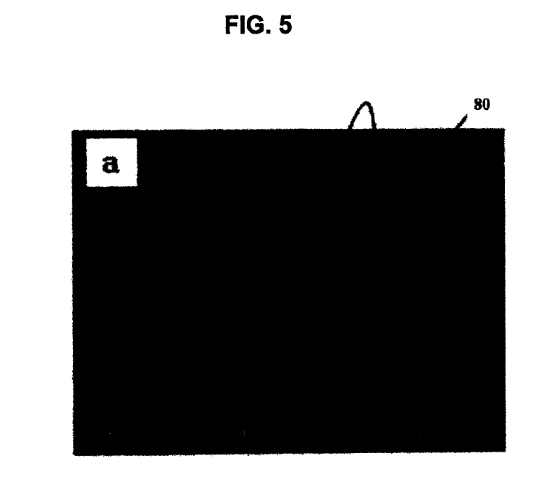

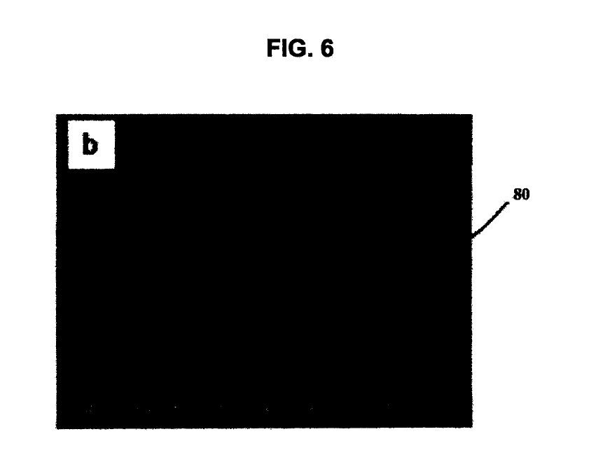

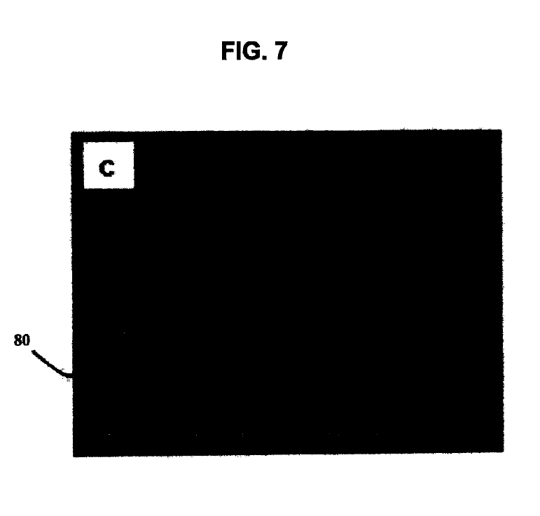

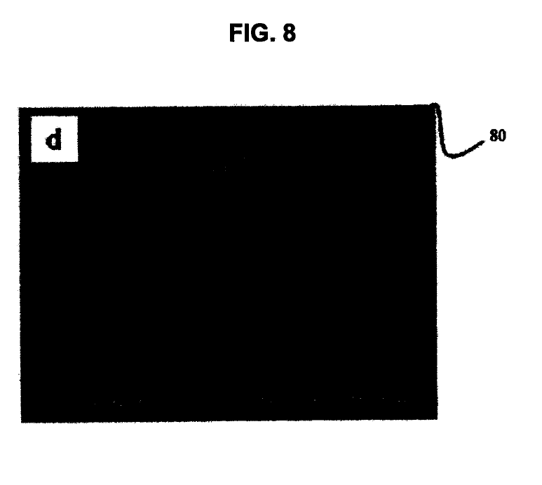

FIGS. 5 to 8 are photographs showing the auxiliary metal electrode of the III-nitride semiconductor light emitting device according to the present disclosure. The auxiliary metal electrode 80 is observed through an scanning electron microscope(SEM). FIG. 5 shows the whole auxiliary metal electrode 80, FIG. 6 shows the auxiliary metal electrode 80 formed on the first n-side electrode, FIG. 7 shows the auxiliary metal electrode 80 formed on the second n-side electrode, and FIG. 8 shows the auxiliary metal electrode 80 formed in the groove. The auxiliary metal electrode 80 formed on the first n-side electrode has a thickness of about 4.4 μm, and the auxiliary metal electrode 80 formed in the groove has a thickness of about 2.8 μm.

Preferably, the thickness of the auxiliary metal electrode 80 ranges from 1 to 10 μm. If the thickness of the auxiliary metal electrode 80 is below 1 μm, a current value per unit area of the electrode is too low to improve an electrical contact characteristic. On the contrary, if the thickness of the auxiliary metal electrode 80 is over 10 μm, a mechanical defect such as separation of the auxiliary metal electrode 80 may occur in a process of cutting and isolating the device.

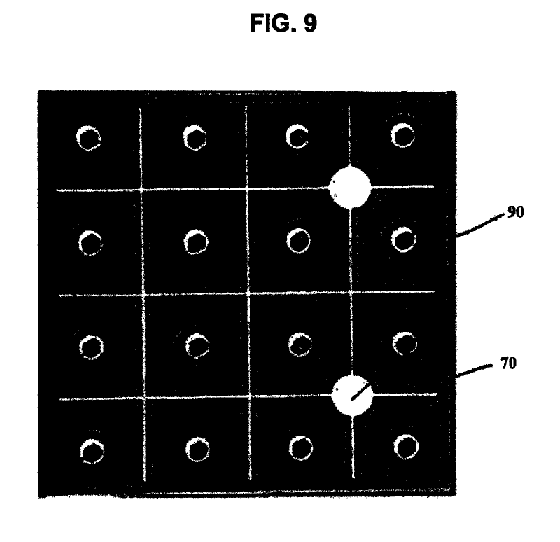

FIG. 9 is a top view illustrating one example of the III-nitride semiconductor light emitting device according to the present disclosure. The light emitting device is a large-area device of 1000 μm×1000 μm with 16 openings 90. Here, p-side bonding pads 70 and a branch electrode extending therefrom surrounds the openings 90.

According to the present disclosure, as the opening 90 is formed at the upper portion of the III-nitride semiconductor light emitting device, it is necessary to arrange the p-side bonding pad 70 and the branch electrode in consideration of the opening 90.

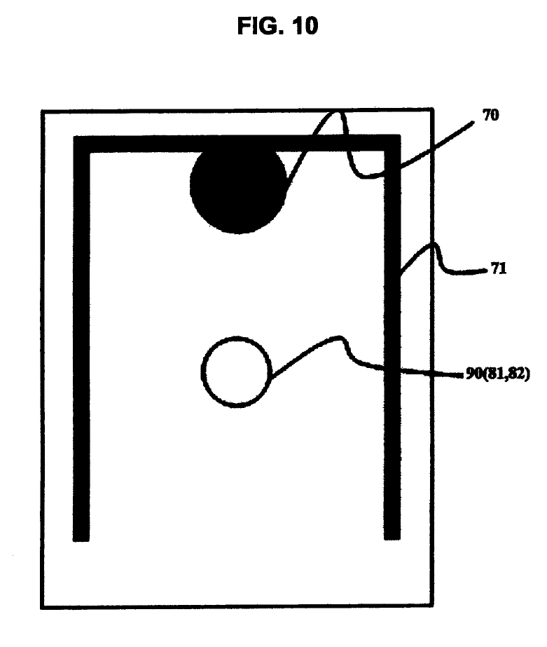

FIG. 10 is a view illustrating one example of a p-side electrode structure of the III-nitride semiconductor light emitting device according to the present disclosure. In the III-nitride semiconductor light emitting device, one opening 90 is positioned at the center, and n-side electrodes 81 and 82 are formed therein. A p-side bonding pad 70 has a ‘[’-shaped branch electrode 71 surrounding the opening 90. Flows of electrons supplied from the n-side electrodes 81 and 82 formed through the opening 90 and holes supplied from the p-side bonding pad 70 are facilitated to improve the luminance of the light emitting device with the vertical electrode structure. As the p-side bonding pad 70 and the branch electrode 71 of the ‘[’ shape are provided, the holes can be smoothly supplied to a p-type nitride semiconductor layer distant from the p-side bonding pad 70, to thereby efficiently apply current. That is, differently from an n-type nitride semiconductor layer with high electron mobility, in the case of the p-type nitride semiconductor layer with low hole mobility, it is important to introduce a current spreading layer for improving a current supply characteristic, and to shape and arrange the p-side bonding pad 70 and the branch electrode 71.

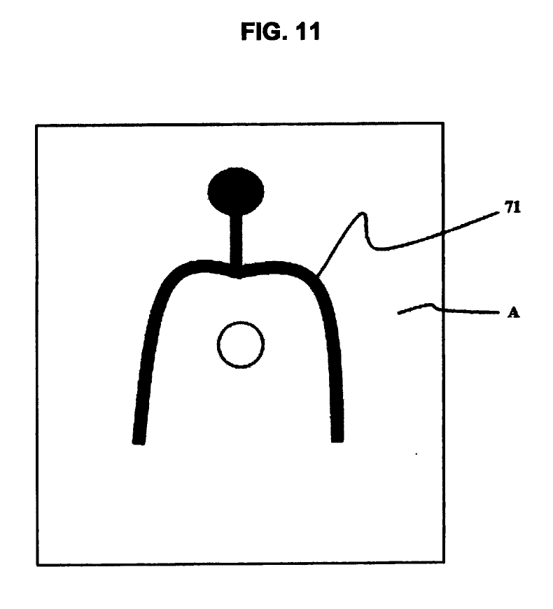

FIG. 11 is a view illustrating another example of the p-side electrode structure of the III-nitride semiconductor light emitting device according to the present disclosure. As a modified example of FIG. 10, a branch electrode 71 of ‘[’ shape has a soft curved line. As compared with the example of FIG. 10, the branch electrode 71 is relatively short to less cover a light emission portion A, which leads to an advantageous effect.

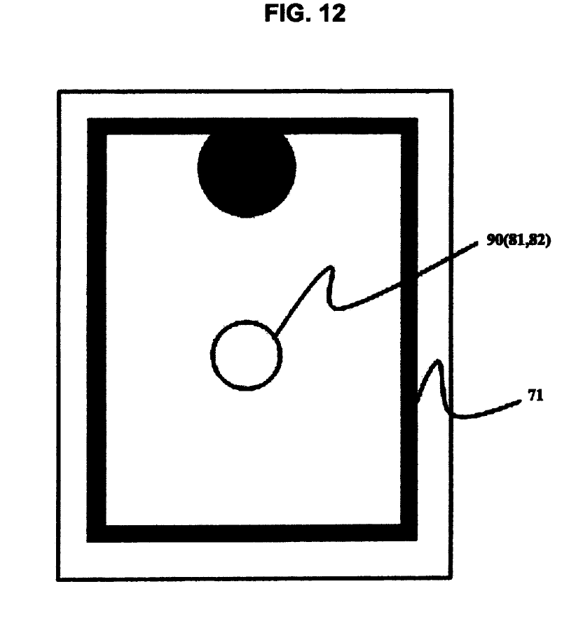

FIG. 12 is a view illustrating yet another example of the p-side electrode structure of the III-nitride semiconductor light emitting device according to the present disclosure. A branch electrode 71 is formed in a closed loop shape to completely surround an opening 90 with n-side electrodes 81 and 82 formed therein. In addition, the branch electrode 71 is formed at the edge portion of the light emitting device, for efficiently supplying current to the whole light emitting device. The branch electrode 71 formed in the closed loop shape to surround the opening 90 can be implemented with a rectangular structure, a circular structure, and a combination structure of a curved line and a straight line.

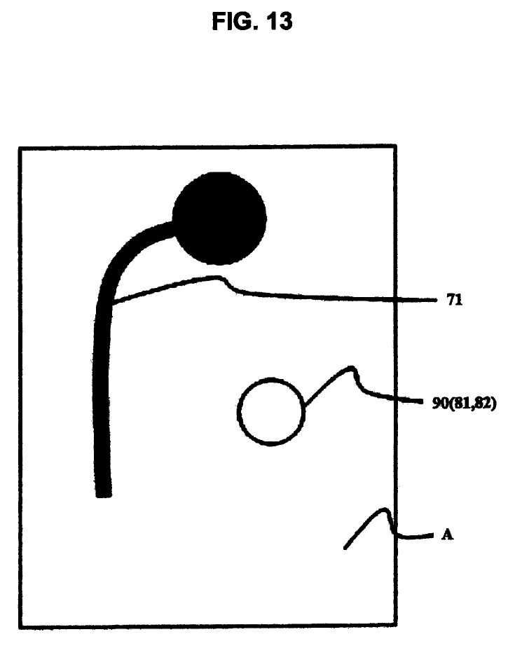

FIG. 13 is a view illustrating yet another example of the p-side electrode structure of the III-nitride semiconductor light emitting device according to the present disclosure, particularly, a position and a shape of a branch electrode 71 in a state where an opening 90 with n-side electrodes 81 and 82 formed therein is formed in a non-central portion of the light emitting device, is shown. When the opening 90 is positioned in the non-central portion of the light emitting device, the branch electrode 71 is formed in a ‘1’ shape to efficiently apply current. As the branch electrode 71 formed in a light emission region A occupies a small area, it does not cause decrease of the luminance of the light emitting device.

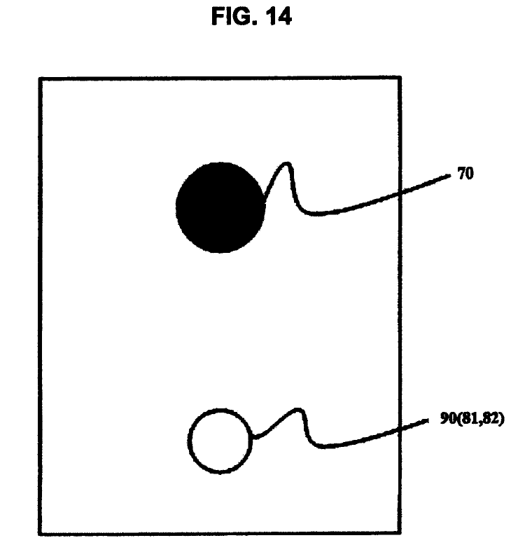

FIG. 14 is a view illustrating yet another example of the p-side electrode structure of the III-nitride semiconductor light emitting device according to the present disclosure. An opening 90 with n-side electrodes 81 and 82 formed therein is positioned in an edge portion of one side of the light emitting device. In this case, a p-side pad electrode 70 is formed at an edge portion of a side opposite to the side close to the opening 90, and a branch electrode is not provided.

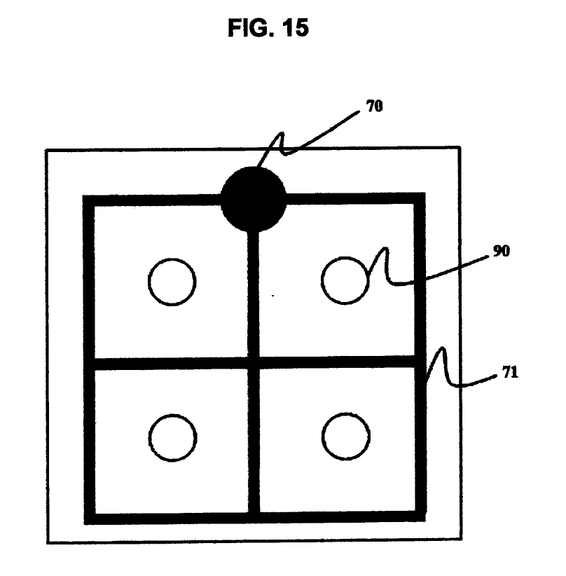

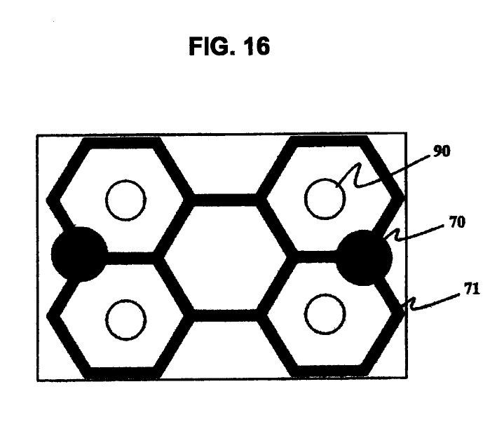

FIGS. 15 and 16 are views illustrating yet another examples of the p-side electrode structure of the III-nitride semiconductor light emitting device according to the present disclosure, particularly, positions and shapes of a p-side bonding pad 70 and a branch electrode 71 in a state where a plurality of openings 90 are formed in the light emitting device. More than one openings 90 are formed in the light emitting device according to the size of the light emitting device. In this case, the branch electrode 71 is formed in an array shape to efficiently supply current to the light emitting device. The array shape of the branch electrode 71 can be a quadrangle, a hexagon, a lozenge, a triangle, a trapezoid, a parallelogram, or a polygon having a curvature which minimizes an area of the branch electrode 71. FIG. 15 shows a quadrangular array-shaped branch electrode 71, and FIG. 16 shows a hexagonal array-shaped branch electrode 71. One or more p-side bonding pads 70 are formed at the crossing points of the branch electrode 71 to maximize the current supply.

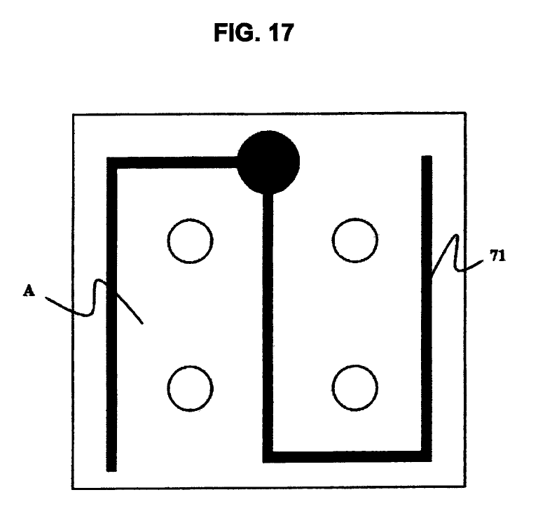

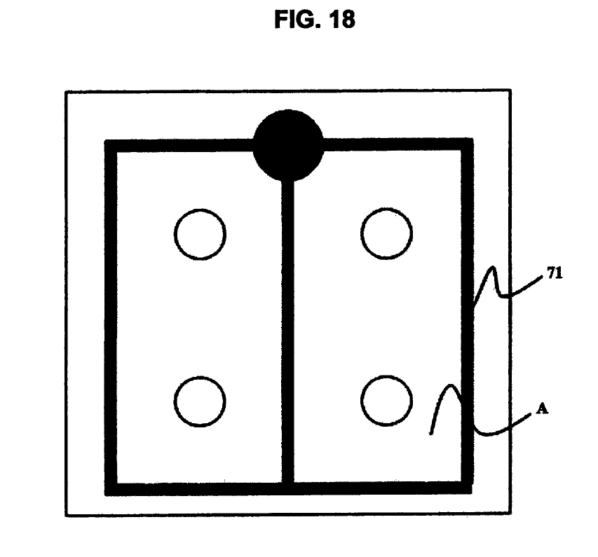

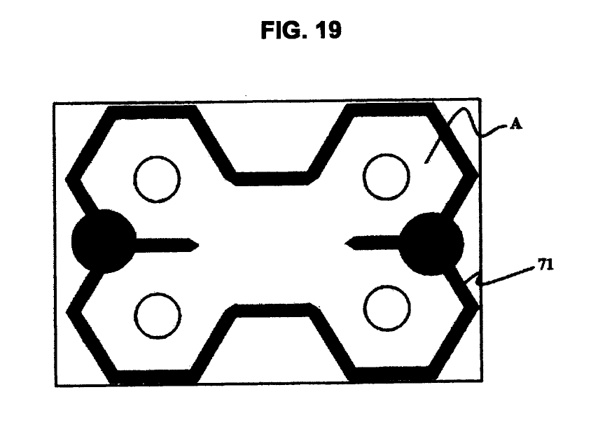

FIGS. 17 to 19 are views illustrating yet another example of the p-side electrode structure of the III-nitride semiconductor light emitting device according to the present disclosure. When the array-shaped branch electrode structure of FIGS. 15 and 16 occupies a large area in a light emission region A, metal materials forming the branch electrode 71 absorb light generated in an active layer, which has a detrimental effect on the light emission efficiency of the light emitting device. In the branch electrode structures of FIGS. 17 to 19, as a part of the branch electrode 71 forming a closed loop is removed, an area of the branch electrode 71 is reduced and current is normally supplied, which results in high light emission efficiency.

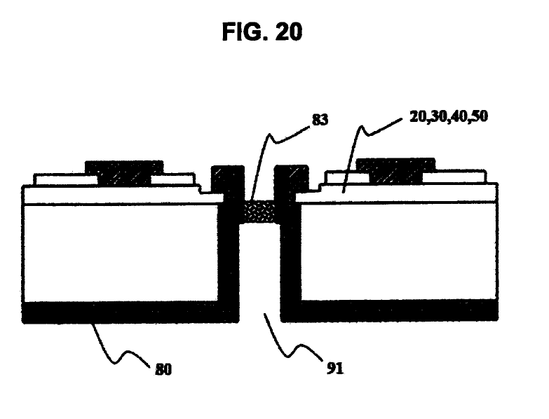

FIG. 20 is a view illustrating another example of the III-nitride semiconductor light emitting device according to the present disclosure. The III-nitride semiconductor light emitting device includes a protection film 83 plated in a groove 91, for preventing a material put at the lower portion of the light emitting device such as epoxy from moving to the upper portion of the light emitting device in packaging. The protection film 83 is formed in the process of forming the auxiliary metal electrode 80 of FIG. 5.

According to a plating method, platinum or phosphorous copper (P: 0.04 to 0.06%) is used as an anode and a wafer to be plated is used as a cathode. A sulfuric acid based solution is employed as an electrolytic solution. The plating solution can be selected from generally used ones or directly prepared. A plating temperature is maintained at 25° C. If the temperature exceeds 30° C., a plating surface is roughened. A current density is adjusted from 1 to 4 A/dm². If the current density is below 1 A/dm², plating speed and plating uniformity are reduced. If the current density is over 4 A/dm², the plating speed is raised, but the surface is roughened and the adhesiveness is weakened. An amount of the plating metal deposited according to a plating thickness is computed as (volume×density). To this end, the plating uniformity can be maintained by a method of compensating for an electrolytic solution according to the number of platings. Normally, one or more of Au, Ag and Cu of superior metal adhesiveness and electrical conductivity are selected to form the protection film 83. Preferably, a thickness of the protection film 83 ranges from 1 to 15 μm. If the protection film 83, namely, the auxiliary metal electrode 80 is too thin, a current value per electrode unit area is too low to improve a contact characteristic. If the protection film 83 is too thick, a mechanical defect such as separation of the plating metal occurs during the isolation of the light emitting device such as chip cutting. According to an example of the present disclosure, an electrolyte temperature is maintained at about 24° C., 2 A/dm² of current is supplied to a two-inch wafer, and the plating time is adjusted to obtain a thickness of 10˜14 μm at a speed of about 0.2 μm per minute. The plating process is performed once. As occasion demands, the plating process can be performed two or more times. In the former, a thin disk-shaped protection film is formed near a plurality of nitride semiconductor layers 20, 30, 40 and 50, and in the latter, a protection film is formed in a much lower portion.

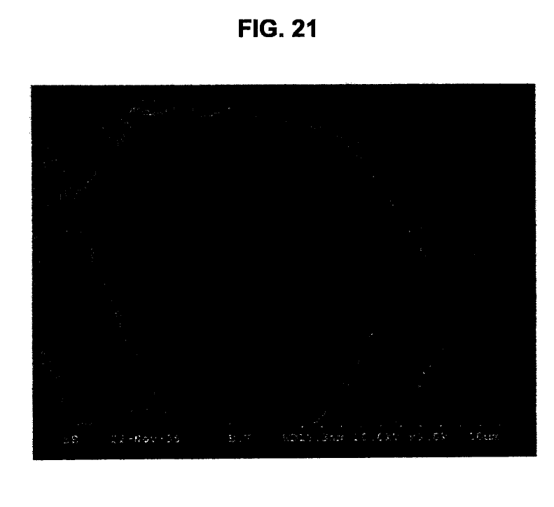

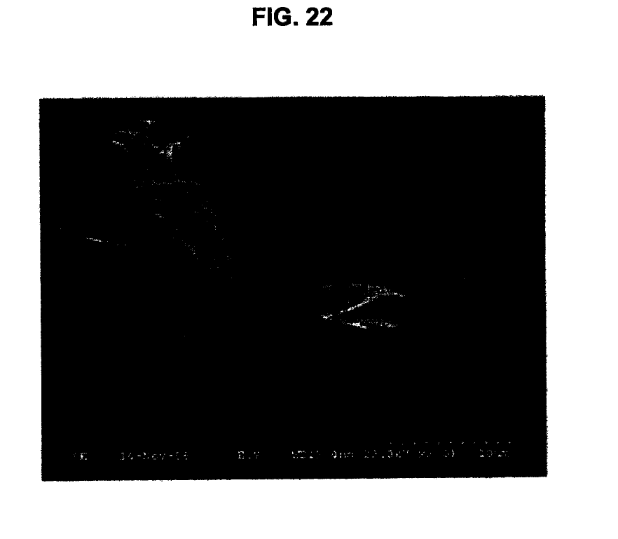

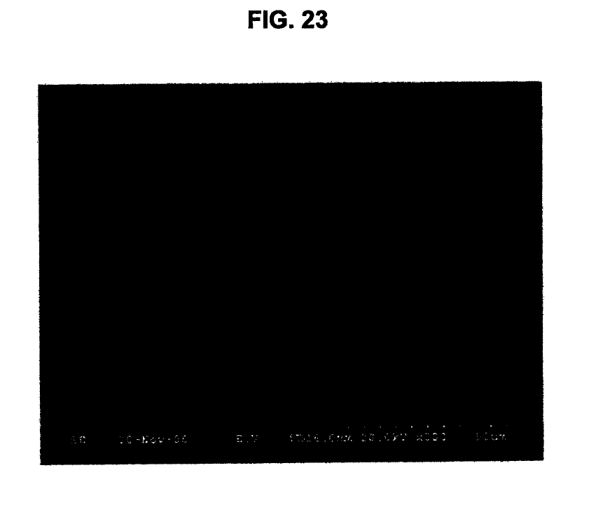

FIGS. 21 to 23 are SEM photographs showing a protection film according to the present disclosure. FIG. 21 is a photograph of a section of a thin protection film with a thickness of about 0.5 μm, taken from the top. As an electrolytic solution is spread in a lateral direction rather than an upward direction with the passage of plating time, a lateral plating probability increases at a nitride semiconductor layer placed over a groove. As a result, as shown in FIG. 22, the protection film is formed in a thin disk shape below the nitride semiconductor layer placed over the groove. Meanwhile, as depicted in FIG. 23, when the plating process is stopped and resumed, a thin disk-shaped protection film is formed in the middle of the groove.

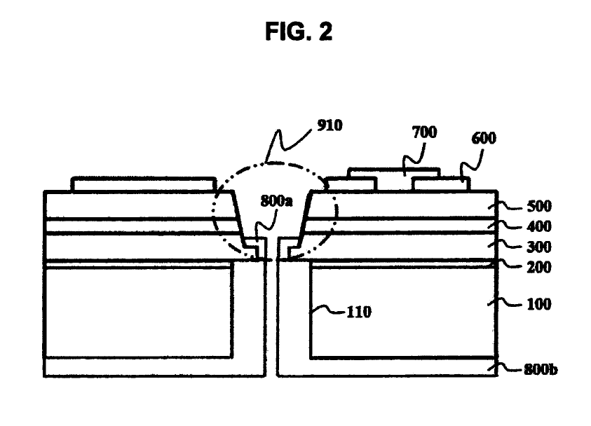

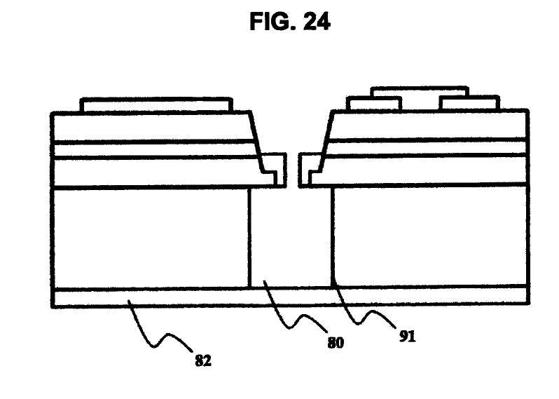

FIG. 24 is a view illustrating yet another example of the III-nitride semiconductor light emitting device according to the present disclosure. Unlike the III-nitride semiconductor light emitting device of FIGS. 2 and 3, the III-nitride semiconductor light emitting device includes an auxiliary metal electrode 80 formed by plating prior to the formation of a second n-side electrode 82, for filling up a groove 91, and the second n-side electrode 82 formed after the plating. In this configuration, since only the second n-side electrode 82 is positioned on the bottom face of the light emitting device, an electrode thickness added to a substrate is reduced, which simplifies the separation of unit light emitting devices. The auxiliary metal electrode 80 functions as the protection film 83 of FIG. 20, and can be formed in the same manner.

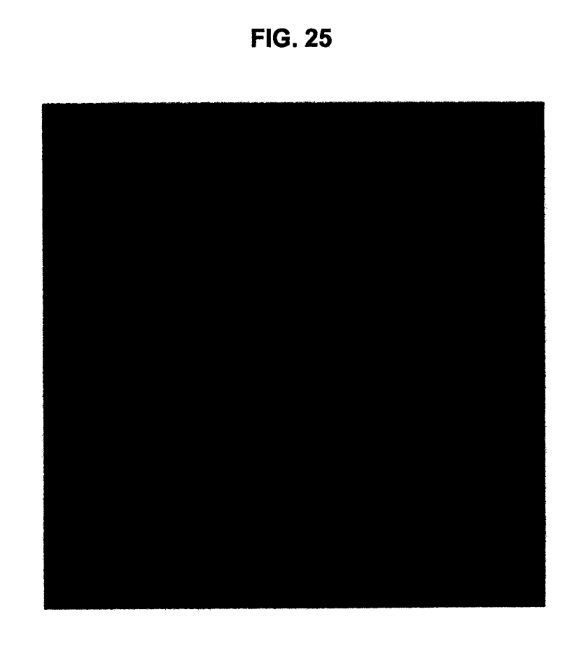

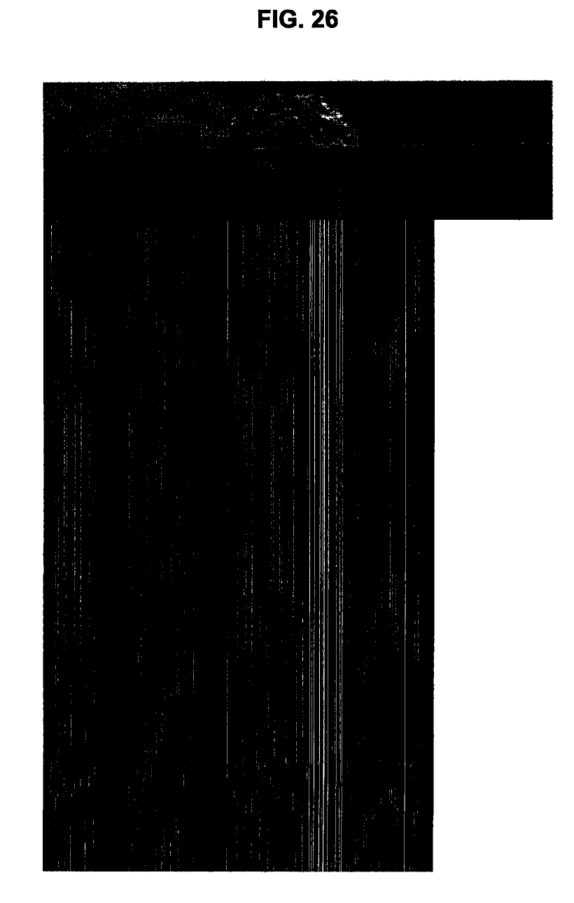

FIGS. 25 and 26 are SEM photographs taken when the groove is excessively filled for explanation's sake. The auxiliary metal electrode 80 is filled in the groove.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

1-6. (canceled)

7. A III-nitride semiconductor light emitting device, including: a substrate; and a plurality of III-nitride semiconductor layers grown over the substrate, and composed of a first III-nitride semiconductor layer with first zconductivity, a second III-nitride semiconductor layer with second conductivity different from the first conductivity, and an active layer positioned between the first III-nitride semiconductor layer and the second III-nitride semiconductor layer, for generating light by recombination of electrons and holes, the III-nitride semiconductor light emitting device, comprising:
a hole connected from the substrate to the first III-nitride semiconductor layer; and
a plating layer positioned in the hole and electrically connected to the first III-nitride semiconductor layer.

8. The III-nitride semiconductor light emitting device of claim 7, comprising an electrode electrically connected from the substrate side to the first III-nitride semiconductor layer through the hole, the plating layer being formed on the electrode.

9. The III-nitride semiconductor light emitting device of claim 7, comprising: a first electrode electrically connected from the side of the plurality of III-nitride semiconductor layers to the first III-nitride semiconductor layer through the hole; and a second electrode electrically connected from the substrate side to the first III-nitride semiconductor layer through the hole, the plating layer being formed to connect the first electrode and the second electrode.

10-24. (canceled)

25. A III-nitride semiconductor light emitting device, comprising:
a substrate in which a groove is formed; a plurality of III-nitride semiconductor layers being formed over the substrate, and including an active layer for generating light by recombination;
an opening formed on the groove along the plurality of III-nitride semiconductor layers; and
a protection film for blocking communication to the opening.

26. The III-nitride semiconductor light emitting device of claim 25, wherein the protection film is a plating film.

27. The III-nitride semiconductor light emitting device of claim 25, comprising an electrode electrically connected to the plurality of III-nitride semiconductor layers through the groove and the opening.

28. The III-nitride semiconductor light emitting device of claim 27, comprising an additional electrode electrically connected to the electrode through the opening.

29. The III-nitride semiconductor light emitting device of claim 25, comprising an electrode electrically connected to the plurality of III-nitride semiconductor layers on the opposite side of the substrate.

30. The III-nitride semiconductor light emitting device of claim 28, comprising a bonding pad electrically connected to the plurality of III-nitride semiconductor layers on the opposite side of the substrate, and formed with the additional electrode.

31. A III-nitride semiconductor light emitting device, comprising:
a substrate in which a groove is formed;
a plurality of III-nitride semiconductor layers being formed on the substrate, and including an active layer for generating light by recombination, and a first III-nitride semiconductor layer positioned between the substrate and the active layer;
an opening formed on the groove along the plurality of III-nitride semiconductor layers;
a first electrode electrically contacting the first III-nitride semiconductor layer through the groove; and
a second electrode electrically contacting the first III-nitride semiconductor layer through the first electrode.

32. The III-nitride semiconductor light emitting device of claim 31 comprising a third electrode electrically contacting the first III-nitride semiconductor layer through the opening.

33. The III-nitride semiconductor light emitting device of claim 31, wherein the first electrode fills up the groove.

34. The III-nitride semiconductor light emitting device of claim 33, wherein the first electrode is electro-plated.

35. The III-nitride semiconductor light emitting device of claim 34, comprising a third electrode electrically contacting the first III-nitride semiconductor layer through the opening.

36. The III-nitride semiconductor light emitting device of claim 35, wherein the first electrode contacts the third electrode.
